(19) United States
(12) Patent Application Publication
(10) Pub. No.: US 2024/0128193 A1
(43) Pub. Date: Apr. 18, 2024

(54) ELECTRONIC MODULE AND ELECTRONIC APPARATUS

(71) Applicant: Advanced Semiconductor Engineering, Inc., Kaohsiung (TW)

(72) Inventors: Pao-Nan LEE, Kaohsiung (TW); Chang Chi LEE, Kaohsiung (TW); Jung Jui KANG, Kaohsiung (TW)

(73) Assignee: Advanced Semiconductor Engineering, Inc., Kaohsiung (TW)

(21) Appl. No.: 17/966,698

(22) Filed: Oct. 14, 2022

(51) Int. Cl. H01L 23/538; H01L 23/00; H01L 23/367; H01L 23/498; H01L 23/552; H01L 25/16

(52) U.S. Cl. CPC H01L 23/5386; H01L 23/3677; H01L 23/49866; H01L 23/5385; H01L 23/552; H01L 24/16; H01L 25/162; H01L 25/165; H01L 2224/16225; H01L 2924/14252; H01L 2924/1427; H01L 2924/1434; H01L 2924/19041; H01L 2924/3025

(57) ABSTRACT

An electronic module is disclosed. The electronic module includes an electronic component and an interconnection structure disposed over the electronic component. The interconnection structure comprises a first region and a second region different from the first region. The first region is configured to transmit a power from outside of the electronic module to the electronic component. The second region is configured to dissipate heat from the electronic component.

### BACKGROUND

### 1. Field of the Disclosure

The present disclosure generally relates to an electronic module and electronic apparatus.

### 2. Description of the Related Art

Power supply units with low power consumption and high heat dissipation are in demand for high performance computing (HPC) systems. Power routing paths for transmitting power signals are usually provided by a system board, over which several dies are mounted. Layout design may be constrained by the need to minimize electromagnetic interference between power signals and non-power signals (e.g., electrical signals), which can limit the ability to miniaturize the system board.

The voltage and power requirements of the dies vary, and the rapid increase in the total number and variety of dies lead to a corresponding increase in the number of power routing paths. One approach to providing more power routing paths is to provide power through the backsides of the dies by using cables. However, this may reduce heat dissipation due to the lack of space for arranging heat dissipating elements over the backsides of the dies. In addition, the power routing paths through the cables are longer than those routed in the system board, and thus, power efficiency may be reduced.

### SUMMARY

In some arrangements, an electronic module includes an electronic component and an interconnection structure disposed over the electronic component. The interconnection structure comprises a first region and a second region different from the first region. The first region is configured to transmit a power from outside of the electronic module to the electronic component. The second region is configured to dissipate heat from the electronic component.

In some arrangements, an electronic module includes a plurality of electronic components and an interconnection structure disposed over the plurality of electronic components. The interconnection structure is configured to provide a plurality of power paths respectively passing through a backside surface of each of the plurality of electronic components.

In some arrangements, an electronic apparatus includes a carrier, a first electronic module disposed over the carrier, and a second electronic module disposed over the carrier. The electronic apparatus also includes a power supply unit configured to transmit a first power to the first electronic module through a first power path without passing through the carrier and to transmit a second power to the second electronic module through a second power path passing through the carrier.

### BRIEF DESCRIPTION OF THE DRAWINGS

Aspects of some arrangements of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a side view of an example electronic apparatus according to some arrangements of the present disclosure.

FIG. 2A illustrates a side view of an example electronic module as shown in FIG. 1 according to some arrangements of the present disclosure.

FIG. 2B illustrates a side view of an example electronic module according to some arrangements of the present disclosure.

FIG. 3A illustrates a top view of a part of an example electronic module according to some arrangements of the present disclosure.

FIG. 3B illustrates a top view of a part of an example electronic module according to some arrangements of the present disclosure.

FIG. 3C illustrates a top view of a part of an example electronic module according to some arrangements of the present disclosure.

FIG. 3D illustrates a top view of a part of an example electronic module according to some arrangements of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

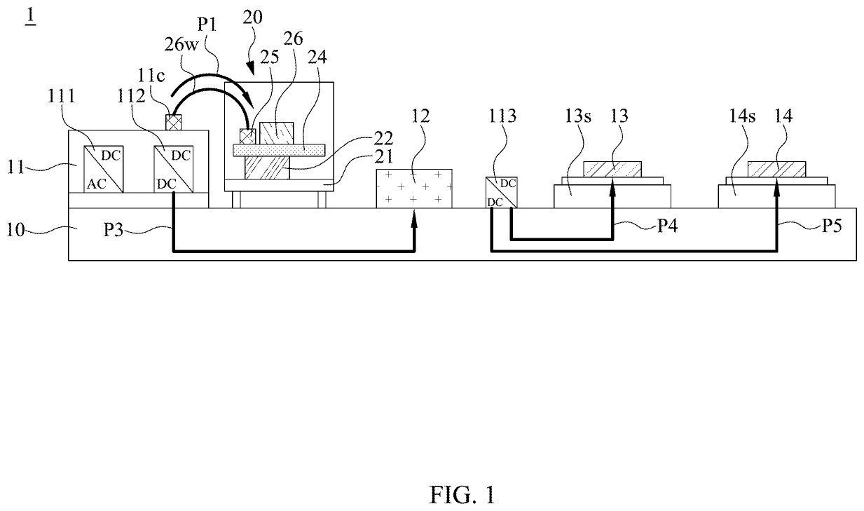

FIG. 1 illustrates a side view of an example electronic apparatus 1 according to some arrangements of the present disclosure. In some arrangements, the electronic apparatus 1 may include a computer system or may be a part of a computer system. The electronic apparatus 1 may be provided to suit different requirements, depending on the intended use of the computer system. For example, the electronic apparatus 1 may be implemented for data transferring, data processing, data management and maintenance, sensors, and other functions. The electronic apparatus 1 may include a carrier 10, a power supply unit 11, electronic modules 12, 20, and electronic components 13, 14.

The carrier 10 may include a system board, a main board, a main printed circuit board (PCB), or so on. In some arrangements, the components (such as the power supply unit 11, the electronic modules 12 and 20, and the electronic components 13 and 14 in FIG. 1) of the electronic apparatus 1 may be located over or attached or operatively coupled to the same carrier 10. In some other arrangements, the electronic apparatus 1 may include multiple separate carriers (each of which can be a carrier such as the carrier 10), and the components described herein may be located over or attached to separate carriers.

The carrier 10 may include an interconnection structure, such as a redistribution layer (RDL), a circuit layer, a conductive trace, a conductive via, etc. The interconnection structure may provide signal paths for the components (e.g., 11, 12, 13, 14, and 20) electrically connected to the carrier 10. For example, the carrier 10 may facilitate and allow communications among the components mounted over it.

In some arrangements, the electronic apparatus 1 may include other peripheral devices or computer hardware such as a hard disk, an input device, an output device, a memory device, a communication device, etc. The carrier 10 may provide slots, sockets, and/or connectors for connecting the other peripheral devices or computer hardware.

The carrier 10 may provide power and/or ground connections to the components electrically connected to the carrier 10. For example, the carrier 10 may be configured to provide, define, construct, or establish power routing paths (or power paths) P3, P4, and P5.

As used herein, a signal path may refer to a path through which an electrical signal (e.g., that conveys information or data) may be transmitted. Such an electrical signal may include either analog or digital signals. As used herein, a power path may refer to a path dedicated to power supply connections.

The power supply unit 11 (e.g., one or more power supply units) may be configured to supply power (or a power signal) for charging and/or operating the components of the electronic apparatus 1 via one or more power paths. The power supply unit 11 may include circuitries, such as an alternating current (AC)-to-Direct Current (DC) (AC/DC) converter 111 and DC-to-DC (DC/DC) converters 112 and 113.

In some arrangements, the power supply unit 11 may include other circuitries or components, such as a carrier (which may be a substrate or a PCB), a component for communication, a microcontroller, power or current sense circuitry, power or current regulation circuitry, etc. One or more of such circuitries or components may be integrated into an assembly by way of an encapsulant. For example, the AC/DC converter 111, the DC/DC converter 112, and other circuitries or components (if any) may be supported by (e.g., placed on) a carrier and encapsulated at least partially by an encapsulant. The DC/DC converter 113 may be external to the encapsulant. However, in some other arrangements, the DC/DC converter 113 may also be encapsulated in the same encapsulant that encapsulates the AC/DC converter 111 and the DC/DC converter 112.

The power supply unit 11 may be disposed over the carrier 10. The positions and number of the power supply units in the electronic apparatus 1 are not intended to limit the present disclosure. For example, the power supply unit 11 may not be disposed over the carrier 10. In some arrangements, the entire power supply unit 11 may be disposed over another carrier separated from the carrier 10. In some arrangements, the DC/DC converter 113 (or other circuitries or components (if any)) may be disposed over another carrier separated from the carrier 10. In some arrangements, there may be another power supply unit for supplying power for charging and/or operating the components of the electronic apparatus 1.

The power supply unit 11 may be configured to convert an input AC (the source of which may originate from a wall socket of mains electricity) to an output DC, to convert an input power to a lower voltage level or to provide further conditioning (e.g., power factor correction, noise suppression, transient impulse protection, etc.) of the input power, and so on. Then, the power supply unit 11 may be configured to provide the low-voltage DC to some components (e.g., the electronic modules 12 and 20, and the electronic components 13 and 14).

In some arrangements, as stated, the power paths P3, P4, and P5 of the power supply unit 11 may be provided by the carrier 10. For example, the power supply unit 11 may be configured to provide power to the electronic module 12 through the power path P3, to provide power to the electronic component 13 through the power path P4, and to provide power to the electronic component 14 through the power path P5.

In some arrangements, the power supply unit 11 may also be configured to provide power without passing through the carrier 10. For example, a power path of the power supply unit 11 may bypass or external to the carrier 10.

In some examples, the power supply unit 11 may be configured to provide power to the electronic module 20 through a cable 26w, corresponding to the power path P1. The cable 26w may include an Ethernet cable, a flexible flat cable (FFC), an insulated wire having a protective casing, or another suitable wired connection. In some arrangements, a flexible printed circuit (FPC) may be used in place of the cable 26w to provide the power path P1. The cable 26w may have one end connected to the power supply unit 11 by a connector 11c and another end connected to the electronic module 20 by a connector 25. The connectors 11c and 25 may each include an RJ45 connector or other suitable wire-to-board connectors.

The power transmitted from the power supply unit 11 to the electronic module 20 may range between about 12.0-18.0 volts and may be received as an input power by a power regulating component 26 in the electronic module 20. The power regulating component 26 may receive the input power from the connector 25, regulate the input power, and provide regulated power (which may range between about 0.6-1.0 volts) to an electronic component 22 of the electronic module 20.

In some arrangements, the power received at the electronic module 12, the electronic component 14, and the electronic component 13 may be lower than the power received at the electronic module 20. For example, the power received at the electronic module 12, the electronic component 14, and the electronic component 13 may range between about 0.6-1.0 volts.

The electronic module 12 may include a switching module. The electronic module 12 may include a network interface module (NIM). The electronic module 12 may be configured to interface incoming signals from outside the electronic apparatus 1 into receivers (not shown in the figures, such as radio frequency (RF) receivers) of the electronic apparatus 1. The electronic module 12 may be configured to connect components (such as computers, printers, and wireless access points) in a network to each other, and allow them to communicate by exchanging data packets. The electronic module 12 may include a smart network interface card (NIC). In some arrangements, the NIC may allow for an Ethernet connection to external components.

The electronic component 13 and the electronic component 14 may respectively be operatively coupled (e.g., mated) using a socket 13s and a socket 14s to the carrier 10. In some arrangements, the carrier 10 may include slots, latches, levers, or clips to hold the electronic component 13 and the electronic component 14 in place.

In some arrangements, the electronic component 13 and the electronic component 14 may each include an active component that relies on an external power supply to control, output, or modify electrical signals. For example, the electronic component 13 and the electronic component 14 may each include a processor, a controller, a memory, or an input/output (I/O) buffer, etc.

For example, the electronic component 13 and the electronic component 14 may each include a system on chip (SoC), a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some arrangements, the electronic component 13 and the electronic component 14 may each include a device package or a bare die. In some arrangements, the electronic component 13 and the electronic component 14 may each include an electronic module.

The electronic module 20 may be electrically connected to the carrier 10 through solder bonding, Cu-to-Cu bonding, or hybrid bonding. In some arrangements, the electronic module 20 may include a high performance computing (HPC) module.

In some arrangements, the electronic module 20, the electronic component 13, and the electronic component 14 may be configured to execute instructions. For example, the electronic module 20, the electronic component 13, and the electronic component 14 may be in communication with a system memory (not shown in the figures). The system memory may be a non-transitory computer-readable media configured to store data and instructions for use by the electronic module 20, the electronic component 13, and the electronic component 14.

The electronic module 20 may be disposed in adjacent to the power supply unit 11 to facilitate the manufacturing process and reduce the length of the cable 26w. Therefore, the voltage drop or the power loss of the power path P1 can be decreased. The electronic module 20 may be disposed closer to the power supply unit 11 than to the electronic component 13 (e.g., a shortest distance between the electronic module 20 and the power supply unit 11 is less than a shortest distance between the electronic module 20 and the electronic component 13). The electronic module 20 may be disposed closer to the electronic component 13 than the power supply unit 11 (e.g., a shortest distance between the electronic module 20 and the electronic component 13 is less than a shortest distance between the electronic module 20 and the power supply unit 11). The positions and number of the electronic modules and the electronic components in the electronic apparatus 1 are not intended to limit the present disclosure. For example, there may be any number of electronic modules and electronic components in the electronic apparatus 1 due to design needs.

According to some arrangements of the present disclosure, by providing power to an HPC module (such as the electronic module 20) through the cable 26w, the power can be transmitted outside of a system board (such as the carrier 10). In other words, the power can be transmitted without passing through the system board. The issue of interference (such as noise or interference generated from the electromagnetic interference (EMI) field) between the power path and a non-power path (such as the signal path) can be significantly reduced or alleviated. More input/output (I/O) pins on the system board may be used to transmit signals. Therefore, the performance of the electronic apparatus 1 can be enhanced.

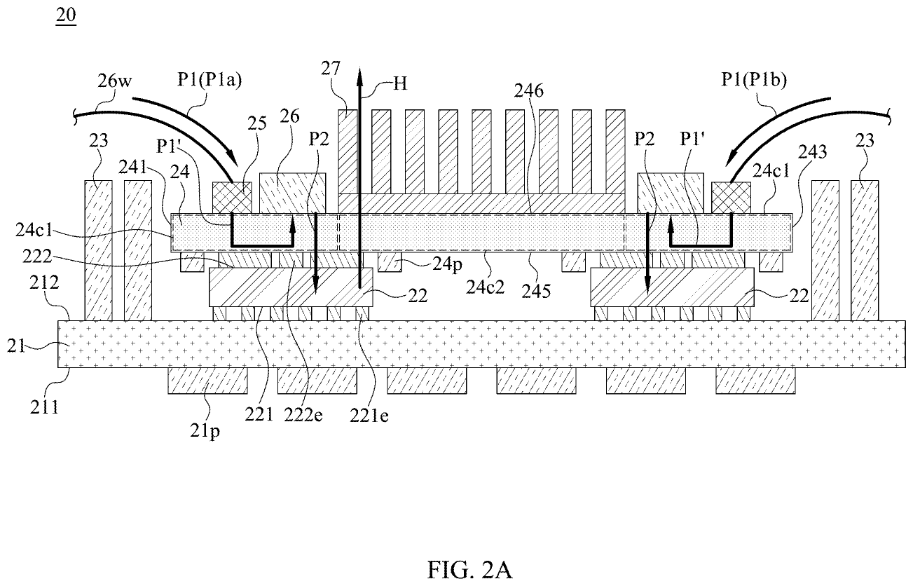

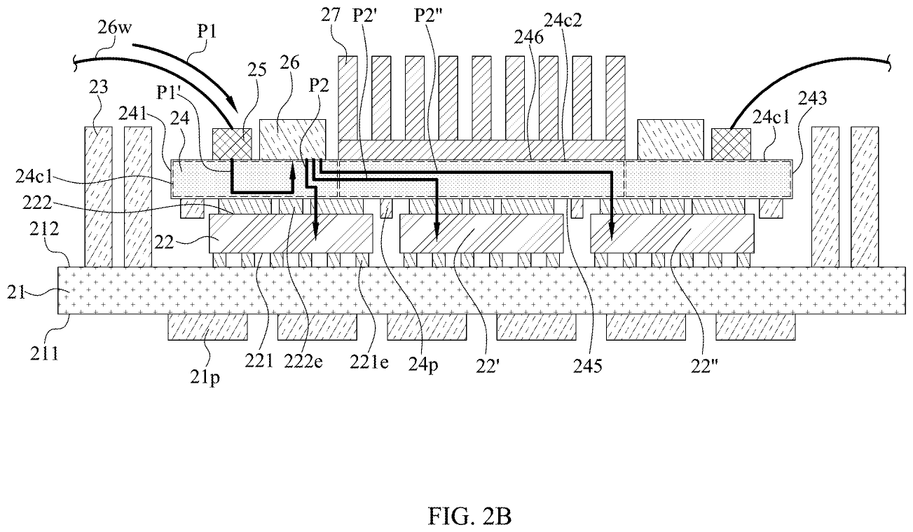

FIG. 2A illustrates a side view of an example electronic module 20 as shown in FIG. 1 according to some arrangements of the present disclosure. Referring to FIGS. 1 and 2A, the electronic module 20 may include a carrier 21, one or more electronic components 22, one or more data storage components 23, an interconnection structure 24, a connector 25, a power regulating component 26, and a heat dissipation element 27.

The carrier 21 may include, for example, a PCB, such as a paper-based copper foil laminate, a composite copper foil laminate, or a polymer-impregnated glass-fiber-based copper foil laminate. In some arrangements, the carrier 21 may include an interconnection structure, such as an RDL, a circuit layer, a conductive trace, a conductive via, etc.

The carrier 21 may include a surface 211 and a surface 212 opposite to the surface 211. The carrier 21 may include one or more conductive pads (not shown) in proximity to, adjacent to, embedded in, and/or exposed from the surfaces 211 and/or 212 of the carrier 21. The carrier 21 may include a solder resist (not shown) on the surfaces 211 and/or 212 of the carrier 21 to fully expose or to expose at least a portion of the conductive pads for electrical connections of the electronic module 20.

In some arrangements, one or more passive components 21p (such as capacitors, inductors, resistors, diodes, fuses or antifuses, etc.) may be disposed over the surface 211 of the carrier 21. The passive components 21p may be circuits or circuit elements needing no an external power source to function and do not provide electrical gain. When the electronic module 20 is disposed over the carrier 10 as shown in FIG. 1, the passive components 21p may be disposed between the carrier 10 and the carrier 21.

The electronic component 22 may be disposed over the surface 212 of the carrier 21. The electronic component 22 may be disposed between the carrier 21 and the interconnection structure 24. The electronic component 22 may include a surface 221 facing the carrier 21 and a surface 222 opposite to the surface 221 and facing the interconnection structure 24. In some arrangements, the surface 221 may include an active surface and the surface 222 may include a backside surface. As used herein, the term “active side” or “active surface” of a component may refer to a side or a surface of an electronic component on which electrical or contact terminals such as contact pads, conductive studs or conductive pillars are disposed, for transmission of electrical signals or power. The “backside,” “inactive side,” or “inactive surface” of a component may refer to a surface of the electronic component on which no contact terminals are disposed.

The electronic component 22 may be electrically connected to the carrier 21 using electrical contacts 221e (or through the electrical contacts 221e) over (e.g., contacting directly) the surface 221. The electronic component 22 may be electrically connected to the interconnection structure 24 using electrical contacts 222e (or through the electrical contacts 222e) over (e.g., contacting directly) the surface 222. In some arrangements, the electrical contacts 221e and 222e may each include a solder ball, such as a controlled collapse chip connection (C4) bump, a ball grid array (BGA), a land grid array (LGA), or so on. In some arrangements, the electrical contacts 221e and 222e may each include a conductive pad, a conductive via, a conductive pillar, a conductive wire, or a combination thereof.

The electronic component 22 may be similar to or is an example implementation of the electronic components 13 and 14 in FIG. 1A. Therefore, some details may correspond to the paragraphs above, and description thereof is not repeated hereinafter for conciseness. In addition, the positions and number of the electronic components in the electronic module 20 are not intended to limit the present disclosure. For example, there may be any number of electronic components in the electronic module 20 due to design needs.

The data storage component 23 may be disposed over the surface 212 of the carrier 21. The data storage component 23 may be disposed next to the electronic component 22 and the interconnection structure 24.

The data storage component 23 may include a non-transitory memory or a non-volatile memory (such as a flash memory and a read-only memory (ROM)) or a volatile memory (such as a Dynamic Random Access Memory (DRAM)). In some arrangements, the data storage component 23 may include a high bandwidth memory (HBM). In some arrangements, the data storage component 23 may be configured to be accessed by the electronic component 22. The data storage component 23 may be configured to support data storage and retrieval operations with the electronic component 22. For example, the data storage component 23 disposed on a first side (such as on the left side) of the interconnection structure 24 may be configured to support data storage and retrieval operations with the electronic component 22 disposed on the left. For example, the data storage component 23 disposed on a second side (such as on the right side) of the interconnection structure 24 may be configured to support data storage and retrieval operations with the electronic component 22 disposed on the right.

The data storage component 23 may include a plurality of memory chips or memory cards. For example, the data storage component 23 can be implemented as two memory chips respectively disposed on two sides of the interconnection structure 24 as shown in FIG. 2A. There may be more or fewer depending on the application. The number of the memory chips may be determined based on, for example, power, cost, heat, and capacity budgets. In some arrangements, the data storage component 23 may also include a memory controller to manage access to the memory chips and provide memory management and maintenance.

The interconnection structure 24 may be disposed over the surface 222 of the electronic component 22. In some arrangements, the interconnection structure 24 may include a component or a connection configured to provide a power path P1′ between the connector 25 and the power regulating component 26 and a power path P2 between the regulating component 26 and the electronic component 22. In some arrangements, the interconnection structure 24 may include a substrate, an interposer, a PCB or a bridge component. In some arrangements, the interconnection structure 24 may include an interposer or include interposer-like wiring to form a structure which may be regarded as an interposer or a fan-out substrate. In some arrangements, the interconnection structure 24 may include a monolithic structure.

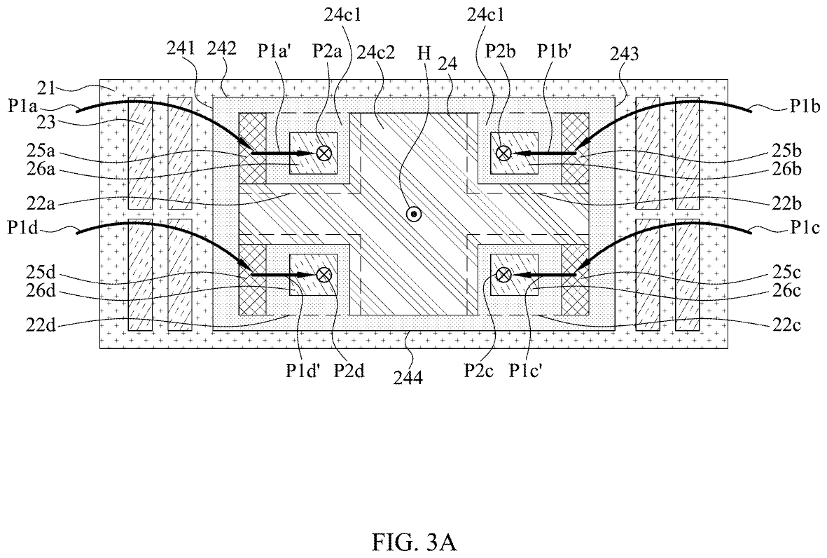

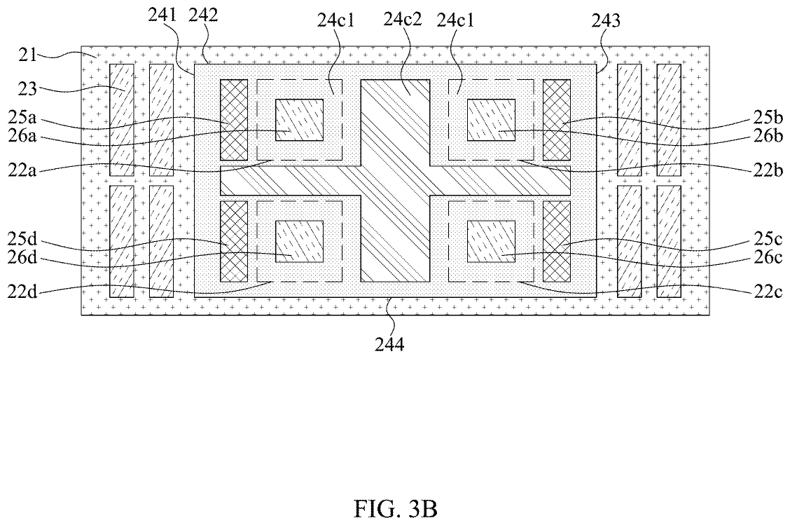

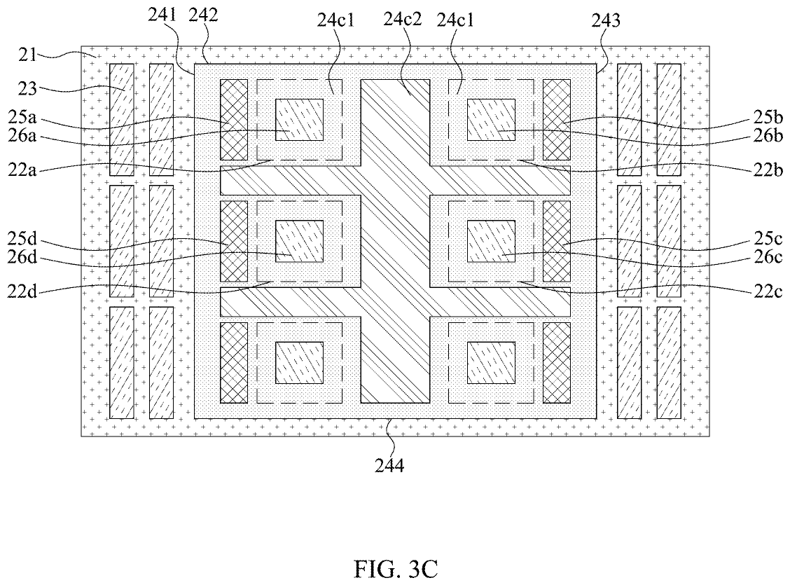

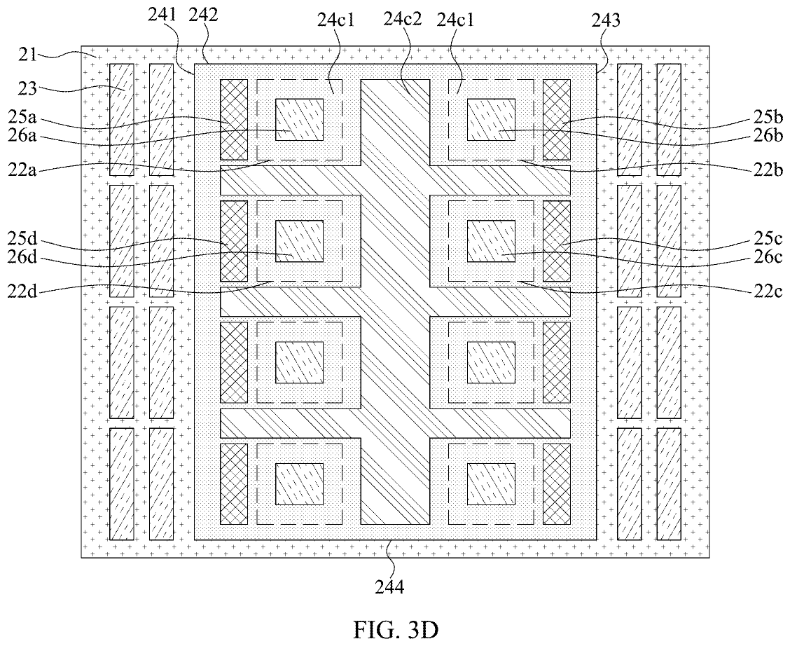

The interconnection structure 24 may include a surface 245 facing the surface 222 of the electronic component 22 and the surface 212, a surface 246 opposite to the surface 245. The surface 246 facing the heat dissipation element 27. From at least FIG. 2A and a top view of FIG. 3A, the interconnection structure 24 may include lateral surfaces (or sides) 241, 242, 243, and 244 extending between the surface 245 and the surface 246.

In some arrangements, one or more passive components 24p (such as capacitors, inductors, resistors, diodes, fuses or antifuses, etc.) may be disposed over or on the surface 245 of the interconnection structure 24. For example, one or more capacitors may be on or adjacent to the surface 245 of the interconnection structure 24. In some arrangements, the capacitor may include a deep trench capacitor (DTC), a multi-layer ceramic capacitor (MLCC), or other capacitors. In some arrangements, the capacitor may be present in (be a part of or construct a part of) or on the power path P2 to provide further conditioning of the power transmitted to the electronic component 22, e.g., the capacitor is a part of the power path P2.

The interconnection structure 24 may include a region (or portion) 24c1 (such as a periphery region) and a region 24c2 (such as a central region). It is noted that the regions 24c1 and 24c2 may not have visible or observable boundaries in the examples in which the interconnection structure 24 is a monolithic structure. The region 24c2 may abut or connect to one or more of the regions 24c1. The multiple regions 24c1 as referred to herein may be one continuous region or two or more discretely separated regions separated by at least one gap. In other arrangements, the region 24c2 may be laterally spaced apart from one or more of the regions 24c1 by a gap or a distance in the examples in which the interconnection structure 24 includes two or more portions spaced apart by the gap or the distance. The regions 24c1 and 24c2 may include or encompass imaginary surface regions or imaginary sections of the interconnection structure 24. In some arrangements, the region 24c1 on the left of FIG. 2A may correspond to a first portion, the region 24c1 on the right may include a second portion, and the region 24c2 may include a third portion extending between the first portion and the second portion. The region 24c2 may be between two parts of the region 24c1 as shown in FIG. 2A. In some examples, the region 24c1 may surround at least a portion of the entirety of the periphery of the region 24c12.

In some arrangements, the regions 24c1 and 24c2 may have different circuit densities, such as different numbers of components, input/output (I/O) pins, routings per unit area, and/or coverage ratio of copper. For example, the region 24c2 may have more conductive components (such as circuit layers, conductive vias, conductive pads, etc.) than the region 24c1. For example, the region 24c2 may have more I/O pins than the region 24c1. For example, the region 24c2 may have more routings per unit area (or higher routing density) than the region 24c1.

For example, the region 24c2 may have a circuit density higher than that of the other regions (such as the regions 24c1) of the interconnection structure 24. For example, the line width (e.g., the width of a line), the line spacing (e.g., the distance or the pitch between two adjacent lines), and/or the pad pitch (e.g., the distance or pitch between two adjacent pads) in the region 24c2 may be lesser than those of the other regions (such as the regions 24c1) of the interconnection structure 24, respectively. For example, the region 24c2 may have a coverage ratio of copper higher than that of the other regions (such as the regions 24c1) of the interconnection structure 24. The coverage ratio of copper may include the amount or the mass per unit area. For example, the surface density of copper over the region 24c2 may be greater than the surface density of copper over the region 24c1. In some arrangements, the heat dissipation rate (or heat dissipation efficiency or heat dissipation performance) of the region 24c2 may be higher than that of the other regions (such as the regions 24c1) of the interconnection structure 24. In other words, the rate by which heat dissipates at the region 24c2 is higher per unit area or volume than the rate by which heat dissipates at another region (e.g., the region 24c1) of the interconnection structure 24.

In some arrangements, one of the regions 24c1 may at least partially overlap with the electronic component 22 in a direction substantially perpendicular to the surfaces 245 and/or 246 of the interconnection structure 24 or to the surfaces 211, 212, 221 and/or 222. In some arrangements, the region 24c2 may at least partially overlap with the electronic component 22 in a direction substantially perpendicular to the surfaces 245 and/or 246 of the interconnection structure 24 or to the surfaces 211, 212, 221 and/or 222.

In some arrangements, the connector 25 and the power regulating component 26 may be disposed on or over the region 24c1 (e.g., directly contacting a surface of the region 24c1). The connector 25 may be configured to receive power from outside of the electronic module 20. For example, the connector 25 may be configured to receive power from the power supply unit 11 (shown in FIG. 1) through the cable 26w (e.g., the path P1 (P1a and P1b). The connector 25 may be electrically connected to the power regulating component 26 using the interconnection structure 24 (or through the interconnection structure 24). In some arrangements, the region 24c1 may be configured to provide the power path P1′ between the connector 25 and the power regulating component 26.

The power regulating component 26 may be electrically connected to the interconnection structure 24 using a flip-chip or wire-bond technique. In some arrangements, the power regulating component 26 may include a power management integrated circuit (PMIC). In some arrangements, the power regulating component 26 may include a voltage regulator, such as a linear regulator (which is configured to maintain a constant output voltage) or a switching regulator (which is configured to generate an output voltage higher than or lower than an input voltage). In some arrangements, the power regulating component 26 may include a step-down (buck) converter, a step-up (boost) converter, an analog-to-digital converter, a digital-to-analog converter, an AC/DC converter, a DC/DC converter, other types of converters, or a combination thereof.

The power regulating component 26 may be configured to receive power from the connector 25 using the interconnection structure 24 (e.g., via the power path P1′). The power regulating component 26 can regulate the power received via the power path P1′ and provide the regulated power to the backside surface (such as the surface 222) of the electronic component 22 (e.g., via the power path P2).

The power regulating component 26 may partially overlap with the electronic component 22 vertically, or be substantially perpendicular to the surfaces 245 and/or 246 of the interconnection structure 24 or to the surfaces 211, 212, 221 and/or 222. The power path P2 between the power regulating component 26 and the electronic component 22 may be substantially perpendicular to the surfaces 245 and/or 246 of the interconnection structure 24 or to the surfaces 211, 212, 221 and/or 222. As such, in comparison with an arrangement where the power transmission path or direction is not vertical between the power regulating component 26 and the electronic component 22, the power path P2 may be shorter, voltage drop thereof may be reduced, and power for the electronic component 22 may be lower.

The positions and number of the connectors in the electronic module 20 are not intended to limit the present disclosure. For example, there may be any number of connectors in the electronic module 20 due to design needs. In some arrangements, a connector may provide power to more than one power regulating component. For example, the power received by the connector 25 may be transmitted to more than one power regulating component through the power paths in the interconnection structure 24.

In some other arrangements, the connector may be omitted. For example, the cable 26w may be directly connected to the power regulating component 26. The power regulating component 26 may be configured to receive power from the power supply unit 11 (shown in FIG. 1) using the cable 26w (or through the cable 26w).

The positions and number of the power regulating components in the electronic module 20 are not intended to limit the present disclosure. For example, there may be any number of power regulating components in the electronic module 20 due to design needs. In some arrangements, a power regulating component may provide power to more than one electronic component, as shown in FIG. 2B. For example, the power regulating component 26 may be configured to provide power to more than one electronic component through the power paths in the interconnection structure 24.

In some arrangements, the electronic component 22 may include different regions configured to perform different functions, receive different types of power control, and/or receive different power voltages. There may be more than one power regulating component configured to provide different voltages to regions of different functions of the electronic component 22.

In some arrangements, the heat dissipation element 27 may be disposed over, adjacent to, or contacting the region 24c2. In some arrangements, a periphery or boundary of a portion of the heat dissipation element 27 that is adjacent to or contacting the interconnection structure 24 defines the periphery or boundary of the region 24c2. The heat dissipation element 27 may at least partially overlap with the electronic component 22 in a direction substantially perpendicular to the surfaces 245 and/or 246 of the interconnection structure 24 or to the surfaces 211, 212, 221 and/or 222. The heat dissipation element 27 may include a heat sink, such as heat dissipation fins as shown, extending along directions substantially perpendicular to the surfaces 245 and/or 246 of the interconnection structure 24 or to the surfaces 211, 212, 221 and/or 222 from a base portion. In some arrangements, the region 24c2 and the heat dissipation element 27 may be configured to provide a heat dissipation path H which extends along direction substantially perpendicular to the surfaces 245 and/or 246 of the interconnection structure 24 or to the surfaces 211, 212, 221 and/or 222 from a base portion. The region 24c2 and the heat dissipation element 27 may be configured to facilitate dissipate heat from the electronic component 22 and externally to the electronic module 20 along the heat dissipation path H.

The regions 24c1 and 24c2 may have different coverage ratios of copper. The regions 24c1 and 24c2 may have different functions. For example, the regions 24c1 (having a lower coverage ratio of copper) may be configured to provide power paths (such as the power paths P1′ and P2) and the region 24c2 (having a higher coverage ratio of copper) may be configured to provide a heat dissipation path (such as the heat dissipation path H). In other words, the interconnection structure 24 may include a monolithic structure that provides different functions, such as power connection and heat dissipation.

According to some arrangements of the present disclosure, by using the interconnection structure 24 to provide power paths P1′ and P2 and the heat dissipation path H, different functions (such as power transmission and heat dissipation) can be completed by using a monolithic structure having different coverage ratios of copper. The components in the electronic apparatus 1 can be less and more compact. The dimensions of the electronic module 20 can be reduced, and the voltage drop of the power path and the signal loss can be decreased without compromising the heat dissipation capacity.

In addition, the power can be transmitted along at least one suitable path outside of the carrier 21. In other words, the power can be transmitted without passing through the carrier 21. The issue of interference (such as noise or interference generated from the EMI field) between the power path and the non-power path (such as the signal path) can be significantly reduced or alleviated. More I/O pins can be provided on the carrier 21 to transmit signals without increasing interference. Therefore, the performance of the electronic module 20 can be enhanced and the space efficacy can be improved.

Furthermore, multiple power regulating components can be disposed over the interconnection structure 24 to provide different types of power control (or different voltages of power) to multiple electronic components. Therefore, the power connections between the power regulating components and the electronic components can be more flexible as more options become available.

FIG. 2B illustrates a side view of an example electronic module according to some arrangements of the present disclosure. The side view in FIG. 2B is similar to the side view in FIG. 2A, with differences therebetween as follows.

The power regulating component 26 may provide power to more than one electronic component. For example, the power regulating component 26 may provide power to the electronic components 22, 22′, and 22″. The power regulating component 26 may be configured to receive power from the connector 25 through the interconnection structure 24 (as indicated by the power path P1′), to regulate the power and to provide the regulated power to the backside surfaces of the electronic components 22, 22′, and 22″.

The power from the power regulating component 26 may be transmitted to the electronic component 22′ through the power path P2′ provided by the interconnection structure 24. The power from the power regulating component 26 may be transmitted to the electronic component 22″ through the power path P2″ provided by the interconnection structure 24. In some arrangements, the power regulating component 26 may provide different types of power control (or different voltages of power) to different ones of the electronic components 22, 22′, and 22″. For example, the power paths P2, P2′, and P2″ may be configured to transmit different power signals, such as different voltages, currents, etc. In some arrangements, the region 24c2 and the heat dissipation element 27 may be configured to provide a heat dissipation path H (similar to what is shown in FIG. 2A) which extends along direction substantially perpendicular to the surfaces 245 and/or 246 of the interconnection structure 24 or to the surfaces 211, 212, 221 and/or 222 from a base portion.

According to some arrangements of the present disclosure, by using the power regulating component 26 to receive power along one or more suitable paths outside of the electronic module and distribute the power to more than one electronic component using the interconnection structure 24, less power regulating components and cables are needed, the electrical connections and the layouts can be simplified, and the cost can be decreased.

FIG. 3A illustrates a top view of a part of an example electronic module according to some arrangements of the present disclosure. In some arrangements, the top view of FIG. 3A may be a top view of the electronic module 20 of FIG. 2A.

The interconnection structure 24 may include the lateral surfaces (or sides) 241, 242, 243 and 244. The data storage components 23 may be disposed along or adjacent to the lateral surfaces 241 and 243. In some other arrangements, the data storage components 23 may be disposed around the interconnection structure 24.

The interconnection structure 24 may be disposed over a plurality of electronic components 22a, 22b, 22c, and 22d. The electronic components 22a, 22b, 22c, and 22d may be similar to the electronic component 22 in FIG. 2A. Therefore, some details may correspond to the paragraphs above, and description thereof is not repeated hereinafter for conciseness. The interconnection structure 24 may cover the electronic components 22a, 22b, 22c, and 22d. For example, the interconnection structure 24 may cover the backside surfaces of the electronic components 22a, 22b, 22c, and 22d.

The region 24c2 of the interconnection structure 24, which has a relatively high circuit density and/or coverage ratio of copper as compared to the region 24c1, may be surrounded by the regions 24c1 of the interconnection structure 24. In some examples, the region 24c1 may be disposed at corners of the interconnection structure 24. In some arrangements, the regions 24c1 may be connected to one another. In some arrangements, the regions 24c1 may be disconnected or separated from one another with at least one gap therebetween. In some arrangements, the regions 24c1 may be separated by the region 24c2. The region 24c2 may extend along two non-parallel directions. For example, the region 24c2 may have a cruciform or cross shape. In some arrangements, the region 24c2 may extend along two adjacent sides of one of the regions 24c1.

In some arrangements, the electronic components 22a, 22b, 22c, and 22d may be disposed under a corresponding one of the regions 24c1. A plurality of connectors 25a, 25b, 25c, and 25d may be disposed over a corresponding one of the electronic components 22a, 22b, 22c, and 22d. In addition, a plurality of power regulating components 26a, 26b, 26c, and 26d may be disposed over a corresponding one of the electronic components 22a, 22b, 22c, and 22d.

The connectors 25a, 25b, 25c, and 25d may be similar to or are example implementations of the connector 25 in FIG. 2A. The power regulating components 26a, 26b, 26c, and 26d may be similar to the power regulating component 26 in FIG. 2A. Therefore, some details may correspond to the paragraphs above, and description thereof is not repeated hereinafter for conciseness.

The electronic components 22a, 22b, 22c, and 22d may receive power using power paths provided by a corresponding one of the regions 24c1 of the interconnection structure 24. For example, the connector 25a may be configured to receive power from outside of the electronic module (such as from the power supply unit 11 shown in FIG. 1), as indicated by a power path P1a. The power from the connector 25a may be transmitted to the power regulating component 26a through one of the regions 24c1, as indicated by a power path P1a′. The power regulating component 26a may receive the power, regulate the power, and provide regulated power to the electronic component 22a, as indicated by a power path P2a. The direction of the power path P2a is into the page.

The configuration of the power paths P1b, P1b′, P2b, the configuration of the power paths P1c, P1c′, P2c, and the configuration of the power paths P1d, P1d′, P2d may be similar to the configuration of the power paths P1a, P1a′, P2a. Therefore, some details may correspond to the paragraphs above, and description thereof is not repeated hereinafter for conciseness. The interconnection structure 24 may be configured to collect a plurality of power signals from outside of the electronic module (such as from the power supply unit 11 shown in FIG. 1) and transmit the plurality of power signals to the electronic components 22a, 22b, 22c, and 22d.

In some arrangements, the connectors 25a, 25b, 25c, and 25d may be disposed closer to the lateral surfaces or sides of the interconnection structure 24 than the power regulating components 26a, 26b, 26c, and 26d. For example, the connector 25a may be closer to the lateral surface 241 of the interconnection structure 24 than the power regulating component 26a. Disposing the connectors 25a, 25b, 25c, and 25d closer to the lateral surfaces may facilitate power connection from outside of the electronic module (such as from the power supply unit 11 shown in FIG. 1) to the connectors 25a, 25b, 25c, and 25d.

In some arrangements, a connector may provide power to more than one power regulating component. For example, the connector 25a may be configured to transmit power to two or more of the power regulating components 26a, 26b, 26c, and 26d using two or more of the power paths P1a′, P1b′, P1c′, and P1d′.

In some other arrangements, as stated with respect to FIG. 2B, a power regulating component may provide power to more than one electronic component. For example, the power regulating component 26a may be configured to provide power to two or more of the electronic components 22a, 22b, 22c, and 22d using two or more of the power paths P2a, P2b, P2c, and P2d.

The heat dissipation path H provided by the region 24c2 may be surrounded by the power paths P2a, P2b, P2c, and P2d. The direction of the heat dissipation path H is out of the page.

FIG. 3B illustrates a top view of a part of an example electronic module according to some arrangements of the present disclosure. The top view in FIG. 3B is similar to the top view in FIG. 3A, with differences therebetween as follows.

In FIG. 3A, the region 24c2 of the interconnection structure 24 overlaps the electronic components 22a, 22b, 22c, and 22d. For example, the electronic components 22a, 22b, 22c, and 22d may each be covered by the region 24c2. In such arrangement, the heat dissipation efficiency may be improved. For example, the region 24c2 with a larger surface area and a better conductivity may be configured to help dissipate heat from the electronic components 22a, 22b, 22c, and 22d.

In FIG. 3B, the region 24c2 of the interconnection structure 24 does not overlap the electronic components 22a, 22b, 22c, and 22d. In such arrangement, the cost of the interconnection structure 24 may be lower. In addition, since the area of the regions 24c1 can be increased, there may be more space available for setting or arranging the power paths P1a′, P1b′, P1c′, and P1d′ and the power paths P2a, P2b, P2c, and P2d. For providing power with low power consumption without compromising the heat dissipation capacity, a heat dissipation element (such as the heat dissipation element 27 in FIG. 2A) may be disposed over the region 24c2.

FIG. 3C illustrates a top view of a part of an example electronic module according to some arrangements of the present disclosure. The top view in FIG. 3C is similar to the top view in FIG. 3B except that FIG. 3C illustrates six electronic components, each provided with a connector and a power regulating component.

FIG. 3D illustrates a top view of a part of an example electronic module according to some arrangements of the present disclosure. The top view in FIG. 3C is similar to the top view in FIG. 3B except that FIG. 3D illustrates eight electronic components, each provided with a connector and a power regulating component.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic module, comprising:
an electronic component; and
an interconnection structure disposed over the electronic component;
wherein the interconnection structure comprises a first region and a second region different from the first region;
wherein the first region is configured to transmit power received from outside of the electronic module to the electronic component; and
wherein the second region is configured to dissipate heat from the electronic component.

2. The electronic module of claim 1, wherein a circuit density in the second region is higher than that in the first region.

3. The electronic module of claim 1, wherein a heat dissipation rate in the second region is higher than that in the first region.

4. The electronic module of claim 3, wherein a coverage ratio of copper in the second region is higher than that in the first region.

5. The electronic module of claim 1, further comprising:
a connector disposed over the first region and configured to be electrically connected to a power supply unit outside of the electronic module, the connector receiving the power from the power supply unit.

6. The electronic module of claim 5, further comprising:
a power regulating component disposed over the first region and electrically connected to the connector using the interconnection structure.

7. The electronic module of claim 6, wherein the power regulating component regulates the power and provide a regulated power to a backside surface of the electronic component.

8. The electronic module of claim 1, further comprising:
a heat dissipation element disposed over the second region and overlaps with the electronic component.

9. An electronic module, comprising:
a plurality of electronic components; and
an interconnection structure disposed over the plurality of electronic components;
wherein the interconnection structure is configured to provide a plurality of power paths respectively passing through a backside surface of each of the plurality of electronic components.

10. The electronic module of claim 9, wherein the interconnection structure comprises:
a first portion covering a backside surface of a first one of the plurality of electronic components;
a second portion covering a backside surface of a second one of the plurality of electronic components; and
a third portion extending between the first portion and the second portion, and wherein the third portion does not cover the first electronic component and the second electronic component.

11. The electronic module of claim 9, wherein the interconnection structure is configured to provide a heat dissipation path, and the plurality of power paths are disposed around the heat dissipation path.

12. The electronic module of claim 11, wherein the interconnection structure comprises a plurality of first regions configured for providing the plurality of power paths, and a second region separating the plurality of first regions and configured for providing the heat dissipation path.

13. The electronic module of claim 12, wherein the plurality of first regions are disposed at corners of the interconnection structure and configured to receive power from outside of the electronic module.

14. The electronic module of claim 13, further comprising:
a plurality of connectors disposed over the plurality of first regions, and configured to receive the power and transmit the power to the plurality of first regions.

15. The electronic module of claim 9, further comprising:
a first data storage component disposed over a first side of the interconnection structure and configured to support data storage and retrieval operations with a first one of the plurality of electronic components; and
a second data storage component disposed over a second side of the interconnection structure and configured to support data storage and retrieval operations with a second one of the plurality of electronic components.

16. The electronic module of claim 15, further comprising:
a carrier supporting the first data storage component, the first one of the plurality of electronic components, the second data storage component, and the second one of the plurality of electronic components,
wherein the carrier is configured to electrically connect the first data storage component with the first one of the plurality of electronic components, and electrically connect the second data storage component with the second one of the plurality of electronic components.

17. An electronic apparatus, comprising:
a carrier;
a first electronic module disposed over the carrier;
a second electronic module disposed over the carrier; and
a power supply unit configured to transmit a first power to the first electronic module using a first power path external to the carrier and to transmit a second power to the second electronic module using a second power path passing through the carrier.

18. The electronic apparatus of claim 17, wherein the first electronic module is closer to the power supply unit than the second electronic module.

19. The electronic apparatus of claim 17, wherein the first electronic module comprises:
a plurality of electronic components; and
an interconnection structure disposed over the plurality of electronic component, wherein the interconnection structure is configured to collect at least a power from the power supply unit.

20. The electronic apparatus of claim 19, wherein the electronic module further comprises:
a power regulating component configured to regulate the power and transmit a plurality of regulated power to the plurality of electronic components.
